(19) United States
(12) Patent Application Publication
(10) Pub. No.: US 2025/0218919 A1
(43) Pub. Date: Jul. 3, 2025

(54) SEMICONDUCTOR PACKAGE STRUCTURE AND PACKAGING METHOD

(71) Applicant: HEFEI SMAT TECHNOLOGY CO. LTD., HEFEI CITY (CN)

(72) Inventor: Xiaochun TAN, HEFEI CITY (CN)

(21) Appl. No.: 18/980,301

(22) Filed: Dec. 13, 2024

(30) Foreign Application Priority Data
Dec. 29, 2023 (CN) 202311852731.4
Dec. 29, 2023 (CN) 202311853343.8
Dec. 29, 2023 (CN) 202311853351.2

(51) Int. Cl. H01L 23/498; H01L 21/48; H01L 21/56; H01L 23/00; H01L 23/15; H01L 23/31; H01L 23/60

(52) U.S. Cl. CPC H01L 23/49838; H01L 21/4857; H01L 21/565; H01L 23/15; H01L 23/3135; H01L 23/60; H01L 24/16; H01L 24/32; H01L 24/73; H01L 2224/16235; H01L 2224/32113; H01L 2224/73253

(57) ABSTRACT

The present application discloses a semiconductor package structure and a packaging method. The semiconductor package structure includes a ceramic base and a lower package body. A crystal sheet is disposed in a groove at an upper surface of the ceramic base. The lower package body includes a first encapsulation layer which encapsulates a semiconductor chip and a second encapsulation layer which encapsulates a wiring layer. An active surface of the semiconductor chip is located inside the first encapsulation layer and is electrically coupled to the wiring layer. The ceramic base and the lower package body according to the present disclosure may be produced separately and then assembled. The package body may be produced in batches and then diced, which increases production efficiency and greatly reduces manufacturing costs. It also helps relieve mechanical stress, ensuring structural stability.

### CROSS-REFERENCE TO RELATED APPLICATION(S)

This application claims priority to Chinese patent application of invention No. 202311852731.4 filed on Dec. 29, 2023, entitled “SEMICONDUCTOR PACKAGE STRUCTURE AND PACKAGING METHOD”, Chinese patent application of invention No. 202311853343.8 filed on Dec. 29, 2023, entitled “CRYSTAL OSCILLATOR AND PACKAGING METHOD THEREFOR”, Chinese patent application of invention No. 202311853351.2 filed on Dec. 29, 2023, entitled “CRYSTAL OSCILLATOR SHIELDING STRUCTURE AND PACKAGING METHOD THEREFOR”, the contents of which are incorporated herein by reference, including the full text of the specification, claims, drawings and abstract.

### TECHNICAL FIELD

The present disclosure relates to the technical field of semiconductor package design, and more particularly, to a semiconductor package structure and a packaging method.

### BACKGROUND

A crystal oscillator is used in a mobile phone or electronic watch with a time display function, that is, there must be a clock crystal oscillator to control the display of time. The principle of a crystal oscillator is to use a crystal that can convert electrical energy into mechanical energy and vice versa, operating in a resonant state to provide stable and precise single-frequency oscillations. At present, there are many types of crystal oscillators, such as clock crystal oscillators.

Some of the conventional crystal oscillator structures use H-shaped ceramics, the crystal oscillator structure is installed in a groove cavity of an upper part of the H-shaped ceramic, and the semiconductor chip is installed in the groove cavity of a lower part of the H-shaped ceramic, and the circuit connection and electrical direction are provided.

Chinese Patent Application No. CN202210058259.6 proposes a crystal oscillator, which uses a ceramic package with an H-shaped structure, and can suppress the generation of a gap between the bottom surface of the IC chamber and the IC chip. The crystal oscillator includes: a crystal chamber with two crystal pads for a crystal sheet, an IC chamber with two monitoring pads at the bottom of the IC chamber in an area other than the area where the IC chip is encapsulated, and a bottom filler. The area at the bottom of the IC chamber, from the first monitoring pad to the specified position below the IC chip, is set as a non-wiring area. The wiring from the first monitoring pads to the crystal pads for the crystal sheet is pulled via a toothed structure. However, the structure in the above patent document uses an H-shaped ceramic base. The H-shaped ceramic base may be a single ceramic base with a special shape, or may be formed by laminating and sintering ceramic raw sheets of many layers. Due to the characteristics of the ceramic, it is easy to break. The process for forming the ceramic base with a special shape is complex, resulting in an expensive ceramic base. The crystal oscillator structure, if using the H-shaped ceramic, can only be produced individually, with wires being arranged inside the ceramic, resulting in a higher unit price of the product, a lower profit margin, and a large rigidity of the H-shaped ceramic. The product experiences significant mechanical stress after soldering, is easy to be damaged. The structure is unreliable, leading to a short service life.

Therefore, it is urgent to provide a semiconductor package structure and a packaging method to solve the above problems.

### SUMMARY

In order to solve the above issues of the conventional H-shaped ceramic base which has complex manufacture process, high production cost, low efficiency, high rigidity, and unstable structure, the present disclosure provides a semiconductor package structure and a packaging method.

According to an aspect of the present disclosure, there is provided a semiconductor package structure comprising: a ceramic base, with a crystal sheet which is disposed in a groove at an upper surface of the ceramic base, and with pads which are electrically coupled to the crystal sheet and are disposed at the bottom of the ceramic base, a lower package body located below the ceramic base, including a first encapsulation layer, which encapsulates a semiconductor chip, and a second encapsulation layer, which encapsulates a wiring layer, wherein the first encapsulation layer is stacked on the second encapsulation layer, an active surface of the semiconductor chip is located inside the first encapsulation layer and is electrically coupled to the wiring layer via conductive bumps, the wiring layer includes first wires for electrically coupling the semiconductor chip to an upper surface of the first encapsulation layer and second wires for electrically coupling the semiconductor chip to a lower surface of the second encapsulation layer.

According to another aspect of the present disclosure, there is provided a packaging method comprising the steps of: forming a lower package body, comprising: encapsulating a semiconductor chip and a wiring layer in a first encapsulation layer and a second encapsulation layer, respectively, the first encapsulation layer being stacked on the second encapsulation layer, an active surface of the semiconductor chip being located inside the first encapsulation layer and electrically coupled to the wiring layer via conductive bumps, the wiring layer including first wires for electrically coupling the semiconductor chip to an upper surface of the first encapsulation layer, and second wires for electrically coupling the semiconductor chip to a lower surface of the second encapsulation layer; forming an upper package body, comprising: disposing a crystal sheet in a groove at an upper surface of a ceramic base, with pads being provided at the bottom of the ceramic base and being electrically coupled to the crystal sheet, and a cover plate being provided above the groove at the upper surface of the ceramic base; attaching, comprising: attaching the lower package under the ceramic base, with a back surface of the semiconductor chip being exposed at an upper surface of the first encapsulation layer to provide an adhesive surface for an adhesive glue, wherein the semiconductor package structure is a crystal oscillator, and the semiconductor chip is used as a control chip of the crystal oscillator.

In the semiconductor package structure according to the embodiment of the present disclosure, a crystal oscillator with a composite package, formed by attaching a lower package body to a ceramic base, replaces the fully ceramic package. The ceramic base and the lower package body can be manufactured separately and then assembled. The package body may be produced in batches and then diced, which increases production efficiency, greatly reduces manufacturing costs, and increases profit margin.

Further, the lower package body includes a first encapsulation layer which encapsulates the semiconductor chip and a second encapsulation layer which encapsulates the wiring layer. A back surface of the semiconductor chip is exposed and used as a hard adhesive surface, which improves interface strength between the ceramic base and the lower package body and improves reliability.

Furthermore, the second encapsulation layer serves as a buffer beneath the semiconductor chip, effectively mitigating both the mechanical stress caused by the rigidity of the ceramic base and the thermal stress generated by the semiconductor chip during operation. This enhances the durability of the semiconductor package structure, ensuring a reliable, stable design with a long service life.

Further, due to a molding process of the semiconductor chip, there is no limitation of the conventional ceramic with a special shape on a placement space of the semiconductor chip due to the sidewall thickness of the ceramic base. This allows for a larger semiconductor chip, which in turn enhances processing capabilities.

In a preferred embodiment, by encapsulating a ceramic base in a third encapsulation layer to form an upper package body, and then electrically interconnecting the upper package body and the lower package body, and then sealing and protecting a cover plate, the ceramic base has an interior space with air tightness. The cover plate is not exposed to air, and thus is not easy to be corroded. A normal function of the crystal oscillator may be ensured, with a long service life.

In a preferred embodiment, when the crystal oscillator is used in an environment such as a watch or the like, which is surrounded by many high-frequency devices, a shield cover

Furthermore, the ceramic base is encapsulated with a third encapsulation layer, with a plastic encapsulant positioned between the metal shield and the ceramic base. This plastic encapsulant helps to relieve stress and prevents the shield from exerting pressure on the ceramic base of a different material, which could otherwise cause damage.

### BRIEF DESCRIPTION OF THE DRAWINGS

FIG. 1 is a perspective view of a conventional semiconductor package structure;

FIG. 2 is a cross-sectional view of a conventional semiconductor package structure;

FIG. 3 is a perspective view of a semiconductor package structure according to a first embodiment of the present disclosure;

FIG. 4 is a cross-sectional view of a semiconductor package structure according to a first embodiment of the present disclosure;

FIG. 5 is a cross-sectional view of a semiconductor package structure according to a second embodiment of the present disclosure;

FIG. 6 is a cross-sectional view of a semiconductor package structure according to a third embodiment of the present disclosure;

FIGS. 7 to 17 are schematic diagrams of package body at various steps of a semiconductor packaging method according to a fourth embodiment of the present disclosure;

FIG. 18 is a schematic diagram at the step of forming an upper package body in a semiconductor packaging method according to a fourth embodiment of the present disclosure;

FIG. 19 is a schematic diagram at the step of attaching in a semiconductor packaging method according to a fourth embodiment of the present disclosure.

### DETAILED DESCRIPTION

The technical solutions of the present disclosure will be clearly and completely described below in conjunction with the accompanying drawings. Obviously, the described embodiments are part of the embodiments of the present disclosure, and not all embodiments. Based on the embodiments in the present disclosure, all other embodiments obtained by a person of ordinary skill in the art without making creative efforts fall within the scope of protection of the present disclosure.

In the description of the present disclosure, it should be noted that the orientation or position relationship indicated by the terms “center”, “up”, “down”, “left”, “right”, “vertical”, “horizontal”, “inside”, “outside”, etc., is based on the orientation or position relationship shown in the accompanying drawings, and is only for the convenience of describing the present disclosure and simplifying the description, and is not intended to indicate or imply that the device or element referred to must be specifically oriented, constructed and operated in a specific orientation, and therefore cannot be understood as a limitation of the present disclosure.

In the description of the present disclosure, it should be noted that the term such as “mount”, “be coupled to”, or “be connected to” should be understood in a broad meaning. For example, it can be a connection either in a fixed manner or in a detachable manner or integrally; it may be either a mechanical connection or an electrical connection; it may be a direct connection or an indirect connection via an intermediate medium or may be communication between two elements. For those of ordinary skill in the art, the specific meaning of the above terms in the present disclosure can be understood in detail.

A quartz crystal oscillator may be formed by cutting a thin sheet (referred to as a crystal sheet) from a quartz crystal at an azimuthal angle, attaching a metal layer as an electrode on either of two opposite surfaces, and bonding one wire on each electrode and coupling it to a pad, and adding a package case. An IC chip may also be added inside the package of the quartz crystal oscillator to form an oscillating circuit with the quartz crystal. A clock crystal oscillator, commonly known as a clock oscillator, is another name of the quartz crystal oscillator. In electronic products such as mobile phones or watches, it is usually necessary to use crystal oscillators. Its products are generally encapsulated in metal cases, and there are also crystal oscillators encapsulated in glass cases or ceramic cases, such as H-shaped ceramic package.

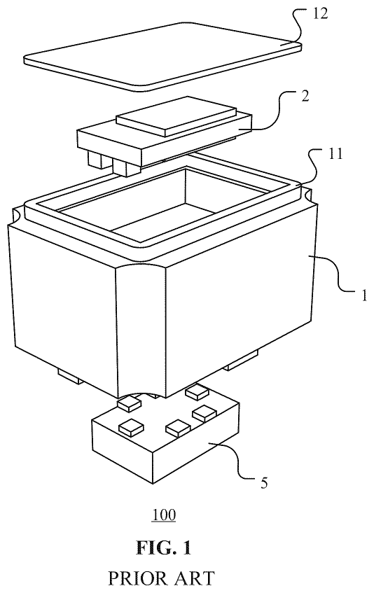

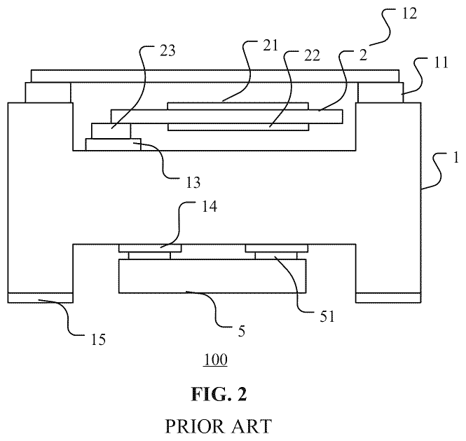

Referring to FIGS. 1 and 2, the crystal oscillator 100 according to the prior art has a full ceramic package. For the sake of clarity, various parts of the crystal oscillator 100 are displayed in an explosion diagram in a perspective view, and actual positions of various parts in the product are shown in a cross-sectional view. The ceramic base 1 has an H-shaped cross-sectional shape, with an upper groove and a lower groove. A crystal sheet 2 is disposed inside the upper groove, and metal layers are formed as electrodes 21 and 22 on two opposite surfaces of the crystal sheet 2. Pads 13 are provided at the bottom of the upper groove. One end of the crystal sheet 2 is secured to and electrically connected to the pads 13, via a conductive adhesive 23. A sealing ring 11 is provided around an opening of the upper groove, and a metal cover plate 12 is covered above the opening of the upper groove, and the metal cover plate 12 contacts the sealing ring 11 to form a sealed space of the upper groove. Inside the lower groove, a semiconductor chip 5 is attached through a solder paste or the like, an active surface of the semiconductor chip 5 faces upward, and conductive bumps 51 are provided on the active surface. Pads 14 are disposed inside the lower groove of the ceramic base. The conductive bumps 51 of the semiconductor chip 5 are attached to the corresponding position inside the lower groove by soldering, so as to achieve an electrical connection between the semiconductor chip 5 and the pads 14.

Wires are provided in the ceramic base 1. Pads 15 are provided at the bottom of the ceramic base, and finally, the entire structure is soldered to a specific position on a circuit board through the pads 15. An electrical connection between the crystal oscillator 100 and an external circuit on the circuit board is achieved through the pad. The ceramic base 1 may be cut from a monolithic ceramic body, or may be formed by laminating and sintering ceramic sheets after being grooved at the corresponding position to have H-shaped cross-sections.

In today's fast-changing world of electronics, cost is certainly an important factor for manufacturers to consider. Due to the characteristics of the ceramic, it is easy to break. The process for forming the ceramic base is complex, resulting in an expensive ceramic base. The crystal oscillator structure, if using the H-shaped ceramic, can only be produced individually, with wires being arranged inside the ceramic, resulting in a higher unit price of the product, a lower profit margin. The H-shaped ceramic has a large rigidity. The product experiences significant mechanical stress after soldering, is easy to be damaged. The structure is unreliable, leading to a short service life. The size of the semiconductor chip 5 is constrained by the sidewall thickness of the ceramic with a special shape. Therefore, it is urgent to provide a semiconductor package structure and a packaging method to solve the above problems.

In order to better understand the object, the structure and the function of the present disclosure, a semiconductor package structure and a packaging method according to the present disclosure are described in detail below in conjunction with the accompanying drawings.

Semiconductor package structures are described below with crystal oscillators as an example, but the present disclosure is not limited thereto. Semiconductor package structures according to embodiments of the present disclosure can be applied for full ceramic package structures with integrated semiconductor chips, including but not limited to: crystal oscillators, power circuit chips, RF circuit chips, etc.

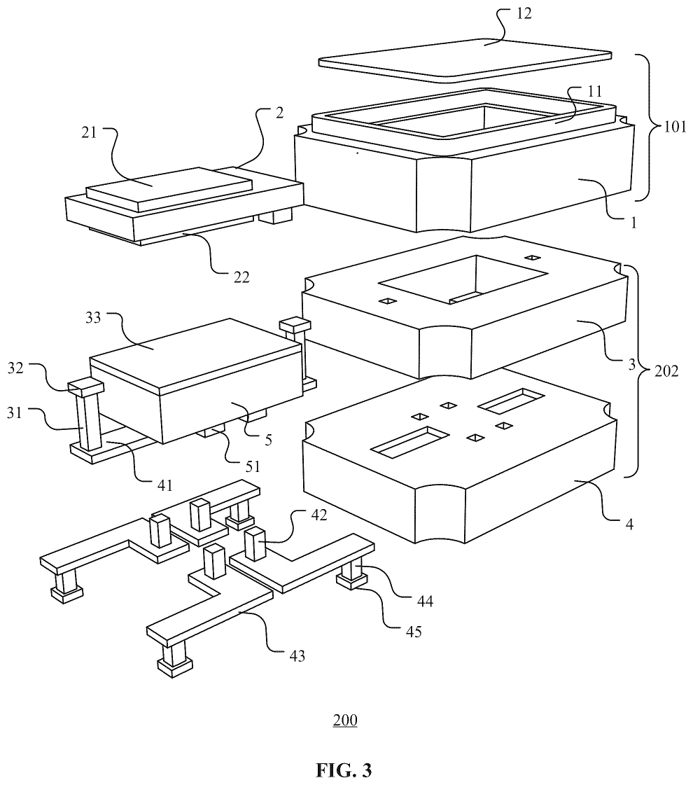

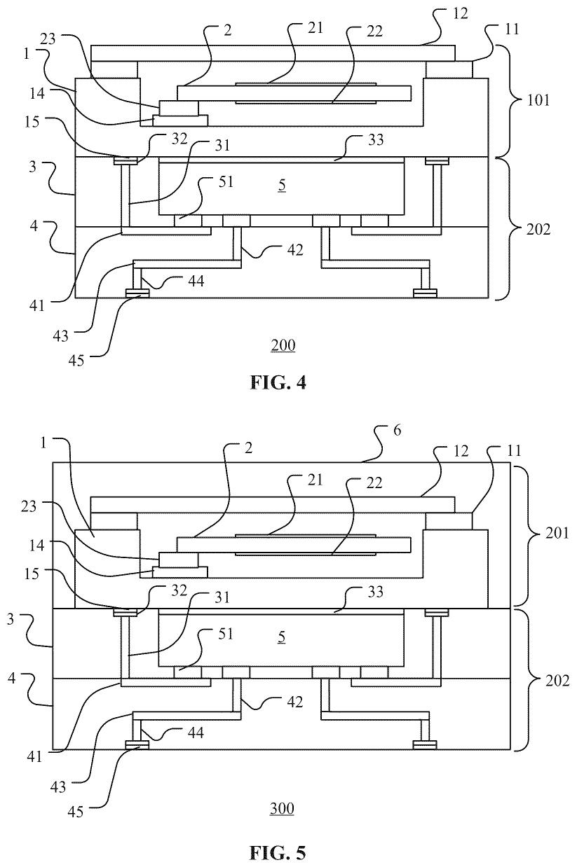

Referring to FIGS. 3 and 4, the semiconductor package structure according to the first embodiment of the present disclosure is a composite package structure comprising a ceramic package and a plastic package. Here, for the sake of clarity, various parts of the crystal oscillator 200 are displayed in an explosion diagram in a perspective view, and actual positions of the various parts in the product are shown in a cross-sectional view. The semiconductor package structure 200 includes an upper package body 101 and a lower package body 202, in a ceramic package and a plastic package, respectively.

The upper package body 101 includes a ceramic base 1 having a concave-shaped cross-sectional shape with a groove opened at an upper surface. A crystal sheet 2 is provided inside the groove, and metal layers are formed as electrodes 21 and 22 on two opposite surfaces of the crystal sheet 2. Pads 14 are provided at the bottom of the groove. One end of the crystal sheet 2 is secured to and is electrically connected to the pads 14, via a conductive adhesive 23. A sealing ring 11 is provided around the opening of the upper groove. A metal cover plate 12 is covered above the opening of the upper groove. The metal cover plate 12 contacts the sealing ring 11 to form a sealed space of the upper groove. Wires are provided inside the ceramic base 1. Pads 15 are provided at the bottom of the ceramic base 1. The pads 14 and 15 in the ceramic base 1 are connected to each other via the wires.

The lower package body 202 includes a first encapsulation layer 3 and a second encapsulation layer 4 on which the first encapsulation layer 3 is stacked. For example, the first encapsulation layer 3 and the second encapsulation layer 4 forms an integrated plastic encapsulation structure by a continuous molding process. For example, the first encapsulation layer 3 and the second encapsulation layer 4 are made of epoxy resins, respectively.

The lower package body 202 of the present disclosure is a rectangular or square structure with the size corresponding to that of the bottom surface of the ceramic base.

The first encapsulation layer 3 encapsulates the flipped semiconductor chip 5, with its active surface facing downward and provided with conductive bumps 51. The semiconductor chip 5 is located inside the first encapsulation layer 3, is electrically connected to a wiring layer 41 via the conductive bumps 51, and then reaches pads 32 on an upper surface of the first encapsulation layer 3 via conductive vias 31 through the first encapsulation layer 3. A back surface of the semiconductor chip 5 is exposed at the upper surface of the first encapsulation layer 3 to provide a hard adhesive surface. The back surface of the semiconductor chip 5 is applied with adhesive glue to form an adhesive layer 33. In an assembled state of the upper package 101 and the lower package 202, the back surface of the semiconductor chip 5 in the first encapsulation layer 3 is adhered to the lower surface of the ceramic base 1. The pads 32 at the upper surface of the first encapsulation layer 3 are soldered to the corresponding pads of the ceramic base 1 to improve the interface strength of the ceramic base and the lower package 202 to improve reliability.

The second encapsulation layer 4 encapsulates a wiring layer 43, conductive visas 42 and 44. The wiring layer 41 described above extends laterally on an upper surface of the second encapsulation layer 4, and the wiring layer 43 extends laterally inside the second encapsulation layer 4. The conductive bumps 51 of the semiconductor chip 5 are connected to the wiring layer 43 via the conductive vias 42, which is further connected to pads 45 on the lower surface of the second encapsulation layer 4 via the conductive vias 44. In the use state of the semiconductor package structure 200, the semiconductor package structure 200 is placed on a circuit board, the entire structure is soldered to a specific position on the circuit board by the pads 45 of the semiconductor package structure 200. An electrical connection between the semiconductor package structure 200 and an external circuit on the circuit board is achieved by the pads 45.

In the semiconductor package structure according to this embodiment, the upper package 101 and the lower package 202 may be produced separately and then assembled. The upper package 101 and the lower package body 202 may be produced in batches and then diced, which increases production efficiency and greatly reduces manufacturing costs.

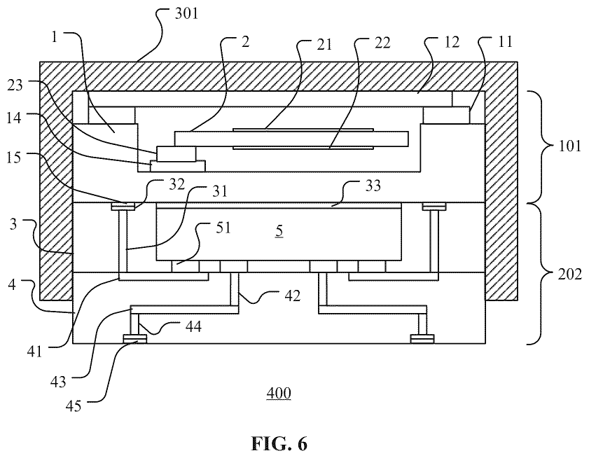

Referring to FIG. 5, the semiconductor package structure according to the second embodiment of the present disclosure is a composite package structure comprising a ceramic package and a plastic package. The semiconductor package structure 300 includes an upper package body 201 and a lower packaged body 202, in a ceramic package and a plastic package, respectively.

The lower package body 202 in the semiconductor package structure 200 according to the second embodiment is the same as the structure of the lower package body 202 in the semiconductor package structure according to the first embodiment, which will not be described in detail. Only the differences between the two embodiments are described below.

The upper package body 201 includes a ceramic base 1 having a concave-shaped cross-sectional shape with a groove opened at an upper surface. A crystal sheet 2 is provided inside the groove, and metal layers are formed as electrodes 21 and 22 on two opposite surfaces of the crystal sheet 2. Pads 14 are provided at the bottom of the groove. One end of the crystal sheet 2 is secured to and is electrically connected to the pads 14, via a conductive adhesive 23. A sealing ring 11 is provided around the opening of the upper groove. A metal cover plate 12 is covered above the opening of the upper groove. The metal cover plate 12 contacts the sealing ring 11 to form a sealed space of the upper groove. Wires are provided inside the ceramic base 1. Pads 15 are provided at the bottom of the ceramic base 1. The pads 14 and 15 in the ceramic base 1 are connected to each other via the wires.

Further, the upper package body 201 further includes a third encapsulation layer 6. The third encapsulation layer 6 encapsulates the ceramic base 1, covering not only the upper surface and side walls of the ceramic base 1, but also the metal cover plate 12 for sealing and protection. The pads 15 of the ceramic base 1 are exposed at the bottom of the third encapsulation layer 6.

In the semiconductor package structure according to this embodiment, the upper package body 201 and the lower package body 202 may be produced separately and then assembled. The upper package 201 and the lower package body 202 may be produced in batches and then diced, which increases production efficiency and greatly reduces manufacturing costs.

In an alternative embodiment, after forming the upper package body 201, the semiconductor chip 5 is attached to the bottom of the ceramic base 1 in the upper package body 201, and then a first encapsulation layer 3 and a second encapsulation layer 4 are formed integrally by a continuous molding process. A plurality of upper packaging bodies 201 may be produced in batches, and together may be used as a substrate for a plurality of lower packaging bodies 202 in the package structure 300. The package structure 300 is then diced, which increases production efficiency and greatly reduces manufacturing costs and increases profit margin.

An upper package body 101 and a lower package body 202 in the semiconductor package structure 400 according to the third embodiment are the same as the corresponding structures in the semiconductor package structure according to the first embodiment, and will not be described in detail here. Only the differences between the two embodiments are described below.

The semiconductor package structure 400 includes a shield cover 301. The shield cover 301 covers at least the upper surface and sidewalls of the ceramic base 1, thereby encapsulates the ceramic base 1. The shield cover 301 and the metal cover plate 12 are both made of metals, and are in contact with each other to form a shield layer together. The shield cover 301 is used to shield the ceramic base 1 to avoid signal transmission outward from the ceramic base 1 and external signal interference with the ceramic base 1, ensuring a normal function of the semiconductor package structure 400.

In a preferred embodiment, the sidewalls of the shield cover 301 extend below the first encapsulation layer 3 so as to encapsulate the semiconductor chip 5, thereby shielding the semiconductor chip 5 to avoid signal transmission outward from the semiconductor chip 5 and external signal interference with the semiconductor chip 5.

In a preferred embodiment, the upper package body 101 further comprises a third encapsulation layer 6. The third encapsulation layer 6 encapsulates the ceramic base 1, covering not only the upper surface and side walls of the ceramic base 1, but also the metal cover plate 12 for sealing and protection. The pads 15 of the ceramic base 1 are exposed at the bottom of the third encapsulation layer 6. The shield cover 301 covers at least the upper surface and sidewalls of the third encapsulation layer 6, thereby encapsulates the third encapsulation layer 6. The shield cover 301 and the ceramic base 1 are separated by a plastic encapsulant. This plastic encapsulant helps to relieve stress and prevents the shield cover 301 from exerting pressure on the ceramic base of a different material, which could otherwise cause damage.

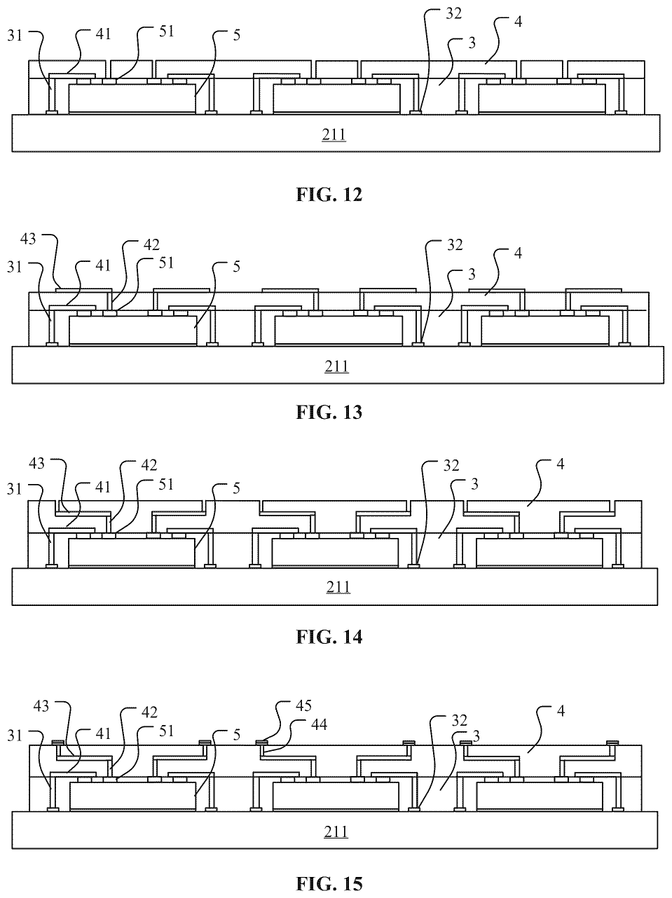

Referring to FIGS. 7 to 19, schematic diagrams illustrating the steps of a semiconductor packaging method according to the present disclosure are shown. The packaging method is used to fabricate the semiconductor package structures 200 shown in FIGS. 3 and 4, and includes the following steps:
forming a lower package body 202: encapsulating a semiconductor chip 5 and wiring layers 41, 43 in a first encapsulation layer 3 and a second encapsulation layer 4, respectively, the first encapsulation layer 3 being stacked on the second encapsulation layer 4; an active surface of the semiconductor chip 5 being located inside the first encapsulation layer 3 and electrically connected to the wiring layers 41, 43 via the conductive bumps 51; the wiring layers 41, 43 comprising a first wiring 41 for electrically connecting the semiconductor chip 5 to an upper surface of the first encapsulation layer 3, and a second wiring 43 for electrically connecting the semiconductor chip 5 to a lower surface of the second encapsulation layer;
forming an upper package body 101: disposing a crystal sheet in a groove at an upper surface of the ceramic base 1, with pads which are electrically connected to the crystal sheet at the bottom of the ceramic base 1, and a cover plate which covers the groove at the upper surface of the ceramic base 1;
attaching, comprising: attaching the lower package body under the ceramic base 1, with a back surface of the semiconductor chip 5 being exposed at the upper surface of the first encapsulation layer 3 to provide an adhesive surface for the adhesive glue.

In one embodiment, the semiconductor package structure is a crystal oscillator, and the semiconductor chip 5 is a control chip of the crystal oscillator. A crystal oscillator with a composite package, formed by attaching the upper package body 101 and the lower package body 202, replaces the fully ceramic package.

Referring to FIGS. 7-17, the above step of forming the lower package bod specifically includes the following sub-steps:

S1: A substrate 211 is provided, on which a plurality of semiconductor chips 5 are arranged, as shown in FIG. 7. The substrate 211 may be an FR-4 substrate which is commonly used in the art. The semiconductor chips 5 are those chips that have passed the electrical test after dicing, each of which includes an oscillating circuit that matches the specifications of the crystal sheet 2 of the ceramic base 1. A plurality of semiconductor chips 5 may be arranged on the substrate 211 at one time, taking three as an example in the present disclosure. An active surface of the semiconductor chip 5 has been formed with conductive bumps 51, and the chip is attached to the corresponding position on the substrate 211 with the active surface facing away by means of adhesive glue. That is, a back surface of the semiconductor chip 5 is attached to the substrate 211. The substrate 211 is electroplated with pads 32 around each of the semiconductor chips 5.

S2: A first encapsulation layer 3 is formed by encapsulating the whole structure for the first time. The conductive bumps 51 at the active surface of the semiconductor chip 5 are exposed at an upper surface of the first encapsulation layer 3, as shown in FIG. 8. Initially, the first encapsulation layer 3 completely encapsulates the semiconductor chip 5 and the pads 32. Then, top surfaces of the conductive bumps 51 of the semiconductor chip 5 are exposed at the surface by polishing the encapsulation surface by mechanical polishing.

S3: The plastic encapsulant is drilled to form holes, which are electroplated with a wiring layer 41 and conductive vias 31, as shown in FIGS. 9 and 10. The plastic encapsulant is drilled to form holes above the pad 32 by a laser, until the pads 32 are exposed at the bottom of the holes. The first encapsulation layer 3 and the holes are electroplated to form a wiring layer 6 at the surface of the first encapsulation layer 3 and in the holes. The wiring layer 6 not only extends laterally at the upper surface of the first encapsulation layer 3, but also fills the holes, thereby forming conductive vias 31. The conductive vias 31 is connected to the pads 32 due to electroplating to ensure an electrical connection. Some of the conductive bumps 51 are electrically connected to the wiring layer 6 due to electroplating.

S4. A second encapsulation layer 4 is formed by encapsulating the whole structure for the second time. The second encapsulation layer 4 is drilled to form holes which expose the conductive bumps 51. Then, a wiring layer 43 is formed at the surface of the second encapsulation layer 4 and conductive vias 42 are formed in the holes by electroplating. The steps of encapsulating, drilling holes and electroplating are repeated in the following steps to complete the lower package body 202, as shown in FIGS. 11, 12, 13, 14, and 15. The present disclosure utilizes a continuous molding process, but is not limited thereto, because the specific process depends on an actual product design.

S5: Finally, the second encapsulation layer 4 is encapsulated again and then is polished to expose pads 45 at an upper surface of the second encapsulation layer 4, as shown in FIG. 16. After completing the electrical connection and the wiring layout, the pads 45 are initially encapsulated and then expose by polishing the second encapsulation layer 4.

S6: Product units of the lower package bodies 202 are diced, as shown in FIG. 17. Finally, the lower package body 202 is encapsulated as a rectangular structure. After mechanically removing the substrate 211, a dicing blade is used to cut vertically along dicing lanes, cutting into the product units of the lower package bodies 202. A back surface of the semiconductor chip 5 and bottom surfaces of the pads 32 are flush with and exposed at the surface of the lower package body 202. Top surfaces of the pads 45 are flush with and exposed at the opposite surface of the lower package body 202. The size of the lower package body 202 corresponds the size of the ceramic base 1, and the lower package body 202 is attached to the ceramic base 1 by adhesive glue at the exposed back surface of the semiconductor chip 5.

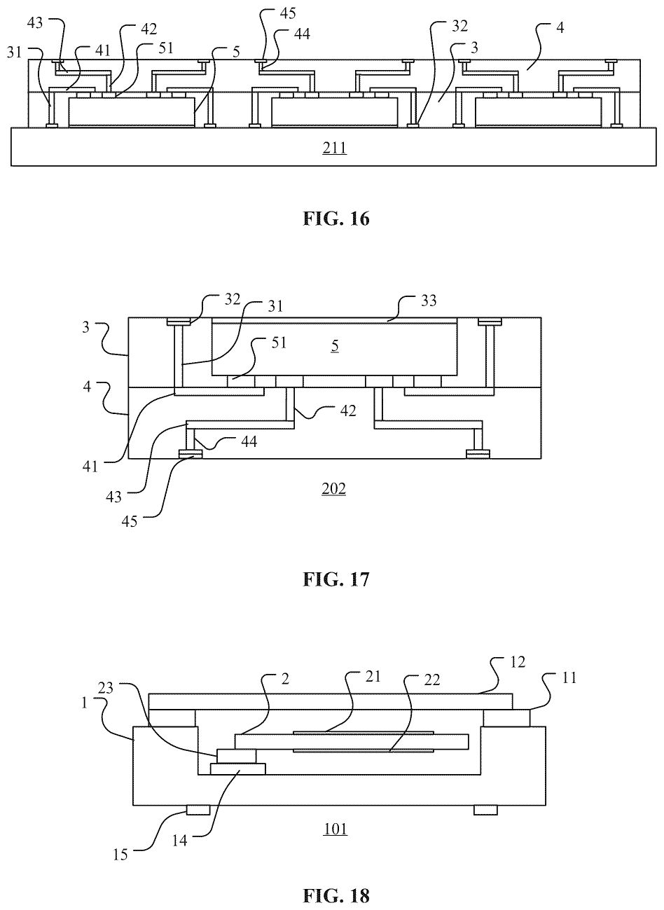

Referring to FIG. 18, the above step of forming the upper package 101 is performed. The ceramic base 1 is commonly used in a conventional structure. The ceramic base 1 and its internal structure as a whole constitute a crystal resonator, briefly as crystal. The resonator is the simplest oscillator without any compensation. A crystal oscillator is formed by electrically connecting the crystal resonator with the semiconductor chip 5 having a built-in oscillator circuit which matches the specifications of the crystal sheet 2 in the ceramic base 1 to achieve a control function. Therefore, the ceramic base 1 in the present disclosure is a crystal resonator, with the following basic structure: a groove is provided at an upper surface of the ceramic base 1 of the ceramic material, that is, a crystal chamber; a crystal sheet 2 is arranged in a plane inside the groove; one end of the crystal sheet 2 is electrically connected to the pads 14 at the bottom of the groove by conductive adhesive; pads 15 are disposed at the bottom of the ceramic base 1; the crystal sheet 2 is electrically connected to the pads 3 through crystals pad and wires; a metal cover plate 12 is disposed above the crystal chamber to seal the crystal sheet 2.

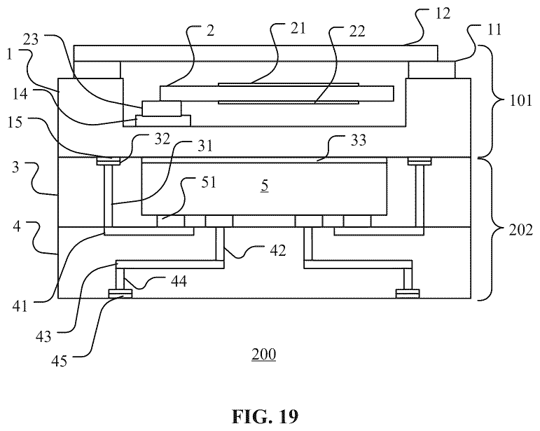

Referring to FIG. 19, the above step of attaching is performed. The lower package body is mounted below the ceramic base 1 through the exposed back surface of the semiconductor chip 5. The exposed pads 6 are electrically connected to the pads 3 to achieve an electrical connection between the semiconductor chip 5 and the crystal sheet 2; The lower package is attached to the bottom position of the ceramic base 1 by applying adhesive glue on the exposed semiconductor chip 5 surface. At the same time, the pads 3 of the ceramic base 1 are electrically connected to the exposed pads 6 of the lower package body by soldering, so that the semiconductor chip 5 is electrically connected to the crystal sheet 2. The crystal sheet 2 is controlled by an oscillating circuit integrated with the semiconductor chip 5, and constitutes together an overall structure of the crystal oscillator. By attaching the ceramic base 1 and the lower package body to form the crystal oscillator, replacing the ceramic crystal oscillator, the lower package body and the ceramic base 1 may be produced separately and then assembled. The lower package body may be produced in batches and then diced, which increases production efficiency and greatly reduces manufacturing costs and increases profit margin by a molding process. A wiring layer 6 in the lower package electrically couples the semiconductor chip 5 to the outside of the lower package. The crystal oscillator structure is soldered to a work area through the exposed pads 6 at the bottom of the lower package. The wiring layer 6 is electrically connected to pads on a printed circuit board by soldering to achieve its functions. The lower package body replaces a ceramic package to solve the problem of a large rigidity of the ceramic. This helps to relieve mechanical stress, and is not easy to be damaged, ensuring a reliable, stable design with a long service life.

In the semiconductor package structure according to the embodiment, the upper package body 101 is a ceramic package and the lower package body 201 is plastic package, respectively. After the upper package body 101 and the lower package body 201 are produced separately, they are assembled to be the composite package structure as shown in FIGS. 3 and 4.

In a preferred embodiment, the semiconductor packaging method according to the embodiment of the present disclosure may include arranging a third encapsulation layer 6 to encapsulate the ceramic base 1 to form the upper package body 201 in the step of forming the upper package body. The upper package body 201 is a composite package and the lower package body is a plastic package, respectively. After the upper package body 201 and the lower package body 201 are produced separately, they are assembled to be the composite package structure as shown in FIG. 5. In this embodiment, the third encapsulation layer 6 seals and protects the metal cover plate 12, exposing the pads 15 of the ceramic base 1 at the bottom of the third encapsulation layer 6.

In a preferred embodiment, the semiconductor packaging method according to the embodiment of the present disclosure may further include arranging a third encapsulation layer 6 to encapsulate the ceramic base 1 to form the upper package body 201 in the step of forming the upper package body. The upper package 201 is a composite package, and a semiconductor chip 5 is attached at the bottom of the upper package 201. A first encapsulation layer 3 and a second encapsulation layer 4 is them formed by a continuous molding process. The preferred semiconductor packaging method can further reduce manufacturing cost and improve profit margin by omitting the step of attaching as described above.

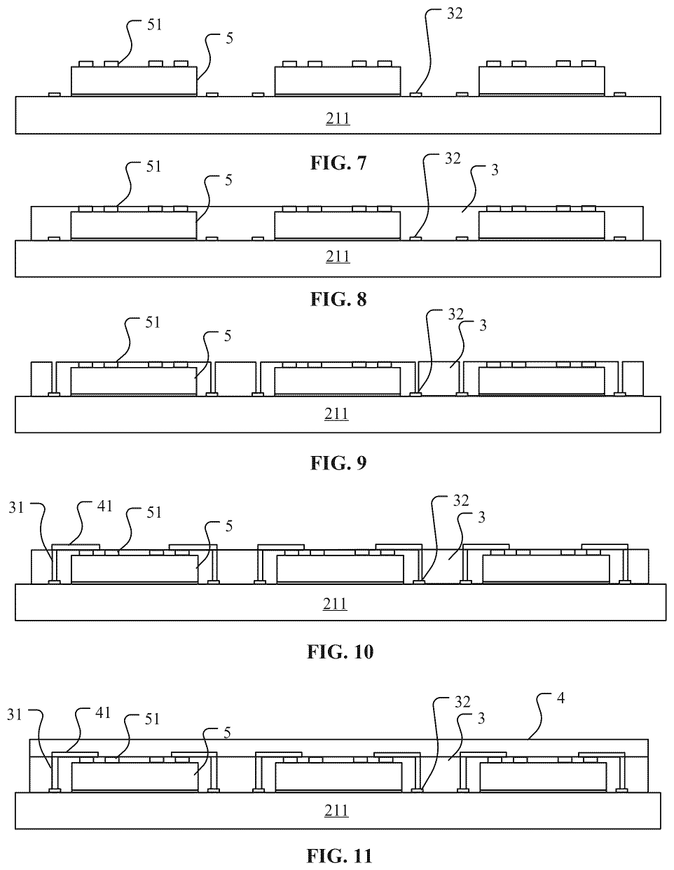

In a preferred embodiment, after the step of attaching as described above, the semiconductor packaging method according to the embodiment of the present disclosure may further include the step of forming a shield cover, to form the composite package structure as shown in FIG. 6. The shield cover 301 covers at least an upper surface and sidewalls of the ceramic base 1, thereby encapsulating the ceramic base, shielding the ceramic base to avoid signal transmission outward from the ceramic base 1 and external signal interference with the ceramic base 1. In the case where the upper package body is formed as a composite package, the shield cover 301 covers at least the upper surface and sidewalls of the third encapsulation layer 6, thereby encapsulating the third encapsulation layer 6. The shield cover 301 and the ceramic base 1 are separated by a plastic encapsulant. This plastic encapsulant helps to relieve stress and prevents the shield cover 301 from exerting pressure on the ceramic base of a different material, which could otherwise cause damage.

In all of the steps using an electroplating process in the present disclosure, an electroplating protection layer is first formed on the surface by exposure and development of photolithography technology, and then a metal seed layer is formed in the area to be electroplated by sputtering or deposition of copper. The metal seed layer in the present disclosure is made of copper. The metal seed layer is used to enhance adhesion between a metal and the area to be electroplated. At the same time, the metal seed layer provides a conductive ion-adhered surface for electroplating to ensure an plating effect.

In all the steps of using a molding process in the present disclosure, a plastic encapsulant is used to form the encapsulation by injection molding. The plastic encapsulant used in the present disclosure is epoxy plastic encapsulant, which has low cost and good curing performance, effectively preventing the corrosion of impurities in the air to the chip circuit and causing the electrical performance of the chip to decline.

In the present disclosure, the lower package body and the ceramic base 1 may be produced separately and then assembled. The lower package body may be produced in batches and then diced, which increases production efficiency and greatly reduces manufacturing costs and increases profit margin. The pads 45 in the lower package body electrically couple the semiconductor chip 5 to the outside of the lower package body. The crystal oscillator structure is soldered to a work area through the exposed pads 45 at the bottom of the lower package. The pads 45 are electrically connected to pads on a printed circuit board by soldering to achieve its functions. The lower package body replaces a ceramic package to solve the problem of a large rigidity of the ceramic. This helps to relieve mechanical stress, and is not easy to be damaged, ensuring a reliable, stable design with a long service life. The semiconductor chip 5 in the lower package body is flipped, which can ensure that an active surface of the semiconductor chip 5 is completely encapsulated in the plastic, and air tightness of the semiconductor chip 5. By encapsulating the semiconductor chip 5 in a plastic, the size of the semiconductor chip 5 may be increased. There is no limitation on the space for disposing the semiconductor chip 5 due to sidewall thickness of the conventional ceramic package of a special shape. This allows for a larger semiconductor chip 5, which in turn enhances processing capabilities.

It is to be understood that the present disclosure is described by way of some embodiments, and it will be understood by those skilled in the art that various alterations or equivalent substitutions may be made to these features and embodiments without departing from the spirit and scope of the present disclosure. Moreover, within the teachings of the present disclosure, these features and embodiments may be modified to suit specific circumstances and materials without departing from the spirit and scope of the present disclosure. Accordingly, the present disclosure is not limited by the specific embodiments disclosed herein, and all embodiments falling within the scope of the claims of the present disclosure fall within the scope of the present disclosure.

What is claimed is:

1. A semiconductor package structure, comprising:
a ceramic base, with a crystal sheet which is disposed in a groove at an upper surface of the ceramic base, and with pads which are electrically coupled to the crystal sheet and are disposed at the bottom of the ceramic base,
a lower package body located below the ceramic base, including a first encapsulation layer, which encapsulates a semiconductor chip, and a second encapsulation layer, which encapsulates a wiring layer,
wherein the first encapsulation layer is stacked on the second encapsulation layer, an active surface of the semiconductor chip is located inside the first encapsulation layer and is electrically coupled to the wiring layer via conductive bumps,
the wiring layer includes first wires for electrically coupling the semiconductor chip to an upper surface of the first encapsulation layer and second wires for electrically coupling the semiconductor chip to a lower surface of the second encapsulation layer.

2. The semiconductor package structure according to claim 1, wherein the first wires are coupled to first pads on an upper surface of the first encapsulation layer via first conductive vias extending in the first encapsulation layer.

3. The semiconductor package structure according to claim 2, wherein the first pads of the lower package body are soldered on corresponding ones of the ceramic base to achieve a mechanical connection between the lower package body and the ceramic base and an electrical connection between the semiconductor chip and the crystal sheet.

4. The semiconductor package structure according to claim 1, wherein the second wires are coupled to second pads on a lower surface of the second encapsulation layer via second conductive vias extending in the second encapsulation layer.

5. The package structure according to claim 4, wherein the second wires are coupled to the conductive bumps of the semiconductor chip via third conductive vias extending in a second encapsulation layer.

6. The package structure according to claim 1, wherein a back surface of the semiconductor chip is exposed at an upper surface of the first encapsulation layer to provide an adhesive surface for an adhesive glue, and the lower package body is attached under the ceramic base by the adhesive glue.

7. The semiconductor package structure according to claim 1, wherein the size of the lower package body corresponds to the size of the ceramic base.

8. The semiconductor package structure according to claim 1, wherein the first encapsulation layer and the second encapsulation layer are formed integrally by a continuous molding process.

9. The semiconductor package structure according to claim 1, wherein the semiconductor package structure is a crystal oscillator, and the semiconductor chip is used as a control chip of the crystal oscillator.

10. The semiconductor package structure according to claim 1, wherein a sealing ring is provided around the groove of the ceramic base, a cover plate is provided above the groove of the ceramic base, and the cover plate is in contact with the sealing ring to form a sealed space of the groove.

11. The semiconductor package structure according to claim 10, further comprising:
a third encapsulation layer, which encapsulates the ceramic base to form an upper package body, and seals and protects the cover plate, exposing the pads of the ceramic base at the bottom of the third encapsulation layer.

12. The semiconductor package structure according to claim 11, wherein the upper package body and the lower package body are formed individually and diced respectively, and then mechanically and electrically connected with each other.

13. The semiconductor package structure according to claim 11, wherein after the upper package body is formed, the semiconductor chip is attached to the upper package body, and then the first encapsulation layer and the second encapsulation layer are formed integrally by a continuous molding process.

14. The semiconductor package structure according to claim 11, wherein the upper package body and the lower package body comprise epoxy resin.

15. The semiconductor package structure according to claim 10, further comprising:
a shield cover, which at least covers an upper surface and a sidewall of the ceramic base, thereby shielding the ceramic base to avoid signal transmission outward from the ceramic base and external signal interference with the ceramic base.

16. The semiconductor package structure according to claim 15, wherein the shield cover is in contact with the cover plate and together forms a shield layer.

17. The semiconductor package structure according to claim 11, further comprising:
a shield cover, which covers at least an upper surface and a sidewall of the third encapsulation layer, thereby shielding the ceramic base to avoid signal transmission outward from the ceramic base and external signal interference with the ceramic base.

18. The semiconductor package structure according to claim 17, wherein the shield cover and the cover plate are separated by the third encapsulation layer and together form a shield layer.

19. The semiconductor package structure according to claim 15, wherein a sidewall of the shield cover extends below the first encapsulation layer, thereby shielding the semiconductor chip to avoid signal transmission outward from the semiconductor chip and external signal interference with the semiconductor chip.

20. The semiconductor package structure according to claim 17, wherein a sidewall of the shield cover extends below the first encapsulation layer, thereby shielding the semiconductor chip to avoid signal transmission outward from the semiconductor chip and external signal interference with the semiconductor chip.

21. A semiconductor packaging method, comprising the steps of:
forming a lower package body, comprising: encapsulating a semiconductor chip and a wiring layer in a first encapsulation layer and a second encapsulation layer, respectively, the first encapsulation layer being stacked on the second encapsulation layer, an active surface of the semiconductor chip being located inside the first encapsulation layer and electrically coupled to the wiring layer via conductive bumps, the wiring layer including first wires for electrically coupling the semiconductor chip to an upper surface of the first encapsulation layer, and second wires for electrically coupling the semiconductor chip to a lower surface of the second encapsulation layer;
forming an upper package body, comprising: disposing a crystal sheet in a groove at an upper surface of a ceramic base, with pads being provided at the bottom of the ceramic base and being electrically coupled to the crystal sheet, and a cover plate being provided above the groove at the upper surface of the ceramic base;
attaching, comprising: attaching the lower package under the ceramic base, with a back surface of the semiconductor chip being exposed at an upper surface of the first encapsulation layer to provide an adhesive surface for an adhesive glue,
wherein the semiconductor package structure is a crystal oscillator, and the semiconductor chip is used as a control chip of the crystal oscillator.

22. The semiconductor packaging method according to claim 21, wherein the size of the lower package body corresponds to the size of the ceramic base.

23. The semiconductor packaging method according to claim 21, wherein the first encapsulation layer and the second encapsulation layer are formed integrally by a continuous molding process.

24. The semiconductor packaging method according to claim 21, wherein, in the attaching step, first pads of the lower package body are soldered on corresponding ones of the ceramic base to achieve a mechanical connection between the lower package body and the ceramic base, and an electrical connection between the semiconductor chip and the crystal sheet.

25. The semiconductor packaging method according to claim 21, wherein, in the step of forming the upper package body, a sealing ring is provided around the groove of the ceramic base so that the cover plate contacts the sealing ring to form a sealed space of the groove.

26. The semiconductor packaging method according to claim 25, wherein, in the step of forming the upper package body, a third encapsulation layer is provided to encapsulate the ceramic base to form an upper package body, the third encapsulation layer seals and protects the cover plate, and pads of the ceramic base are exposed at the bottom of the third encapsulation layer.

27. The semiconductor packaging method according to claim 26, wherein the upper package body and the lower package body are formed individually and diced respectively, and then mechanically and electrically connected with each other.

28. The semiconductor packaging method according to claim 26, wherein after the upper package body is formed, the semiconductor chip is attached to the upper package body, and then the first encapsulation layer and the second encapsulation layer are formed integrally by a continuous molding process.

29. The semiconductor packaging method according to claim 26, wherein the upper package body and the lower package body comprise epoxy resin.

30. The semiconductor packaging method according to claim 25, further comprising:
forming a shield cover, wherein the shield cover at least covers an upper surface and a sidewall of the ceramic base, thereby shielding the ceramic base to avoid signal transmission outward from the ceramic base and external signal interference with the ceramic base.

31. The semiconductor packaging method according to claim 26, further comprising:
forming a shield cover, wherein the shield cover covers at least an upper surface and a sidewall of the third encapsulation layer, thereby enclosing the ceramic base within the shield cover to prevent signal radiation from the ceramic base and external signal interference with the ceramic base.
